(19) United States
(12) Patent Application Publication
(10) Pub. No.: US 2016/0064405 A1
(43) Pub. Date: Mar. 3, 2016

(54) METHOD FOR FORMING INSULATOR FILM ON METAL FILM

(71) Applicant: KABUSHIKI KAISHA TOSHIBA, TOKYO (JP)

(72) Inventors: SHINYA OKUDA, OITA (JP); KEI WATANABE, YOKKAICHI (JP); HIROTAKA OGIHARA, YOKKAICHI (JP); MASAYUKI KITAMURA, YOKKAICHI (JP); TAKESHI ISHIZAKI, NAGOYA (JP); DAISUKE IKENO, YOKKAICHI (JP); SATOSHI WAKATSUKI, YOKKAICHI (JP); ATSUKO SAKATA, YOKKAICHI (JP); JUNICHI WADA, YOKKAICHI (JP)

(21) Appl. No.: 14/610,168

(22) Filed: Jan. 30, 2015

Related U.S. Application Data
(60) Provisional application No. 62/043,804, filed on Aug. 29, 2014.

(51) Int. Cl. H01L 27/115; H01L 21/02; H01L 21/285; H01L 21/28

(52) U.S. Cl. CPC H01L 27/11582; H01L 21/28282; H01L 21/02274; H01L 21/02164; H01L 21/28568; H01L 21/02211

(57) ABSTRACT

According to one embodiment, forming a metal film on an underlying layer, and depositing an oxide film on the metal film using plasma of a mixed gas induced above the metal film. The mixed gas includes a gaseous material source, a gaseous oxidant, and a gaseous reductant.

### CROSS-REFERENCE TO RELATED APPLICATIONS

This application is based upon and claims the benefit of priority from U.S. Provisional Patent Application 62/043,804, filed on Aug. 29, 2014; the entire contents of which are incorporated herein by reference.

### FIELD

Embodiments are generally related to a method for forming an insulator film on a metal film.

### BACKGROUND

A manufacturing process of a semiconductor device includes various processes of forming an insulating film on a metal film. Such an insulating film is, for example, a silicon oxide film. When forming the silicon oxide film on the metal film, a metal oxide may be formed on a surface of the metal film in the forming processes thereof. Many of metal oxides are insulators, then increasing an electrical resistance of the metal film. A metal oxide like this may impair characteristics of the semiconductor device that comprises a thin metal film as an electrode, for example. Thus, a method for manufacturing a semiconductor device capable of suppressing oxidation of the metal film is required.

### BRIEF DESCRIPTION OF THE DRAWINGS

FIG. 1 is a schematic cross-sectional view illustrating a semiconductor device according to an embodiment;

FIG. 2 is a schematic plan view illustrating the semiconductor device according to the embodiment;

FIG. 3, FIG. 4A to FIG. 5B are schematic cross-sectional views showing a manufacturing process of the semiconductor device according to the embodiment;

FIG. 6 is a schematic view showing a film formation apparatus according to the embodiment;

FIG. 7 is a flow chart showing a method for forming an insulating film according to the embodiment; and

FIG. 8A and FIG. 8B are schematic views illustrating characteristics of metal films according to the embodiment and a comparative example.

### DETAILED DESCRIPTION

According to one embodiment, a film formation method includes forming a metal film on an underlying layer, and depositing an oxide film on the metal film using plasma of a mixed gas induced above the metal film. The mixed gas includes a gaseous material source, a gaseous oxidant, and a gaseous reductant.

Various embodiments will be described hereinafter with reference to the accompanying drawings. The same portions in the drawings are labeled with like reference numbers, the detailed description will be omitted, and different portions will be described. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

Furthermore, the disposition and configuration of respective portions will be described using an X-axis, a Y-axis and a Z-axis shown in the figures. The X-axis, the Y-axis and the Z-axis are mutually perpendicular, and represent an X-direction, a Y-direction and a Z-direction, respectively. The Z-direction may be referred to as upward, and the direction opposite to the Z-direction may be referred to as downward.

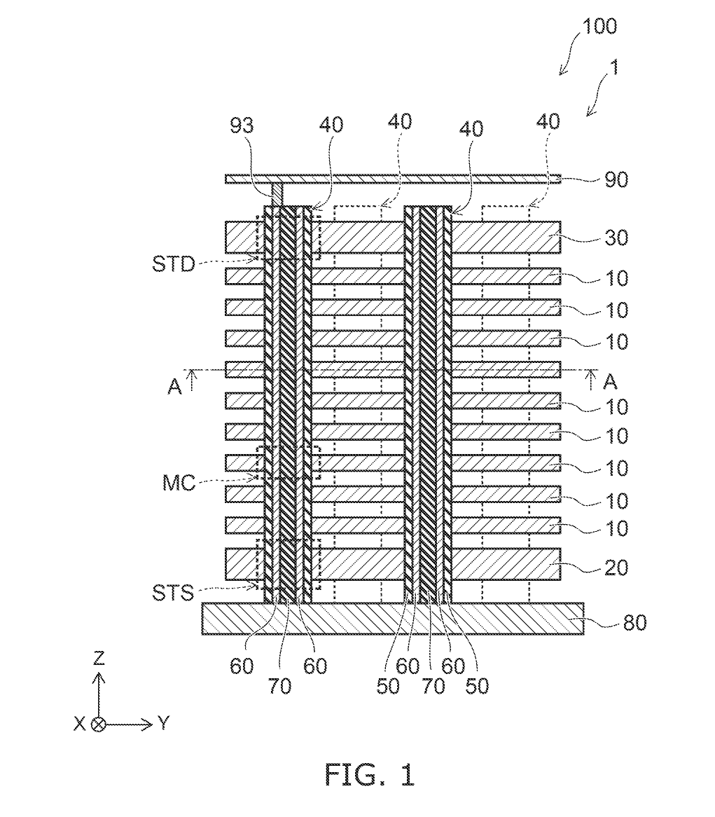

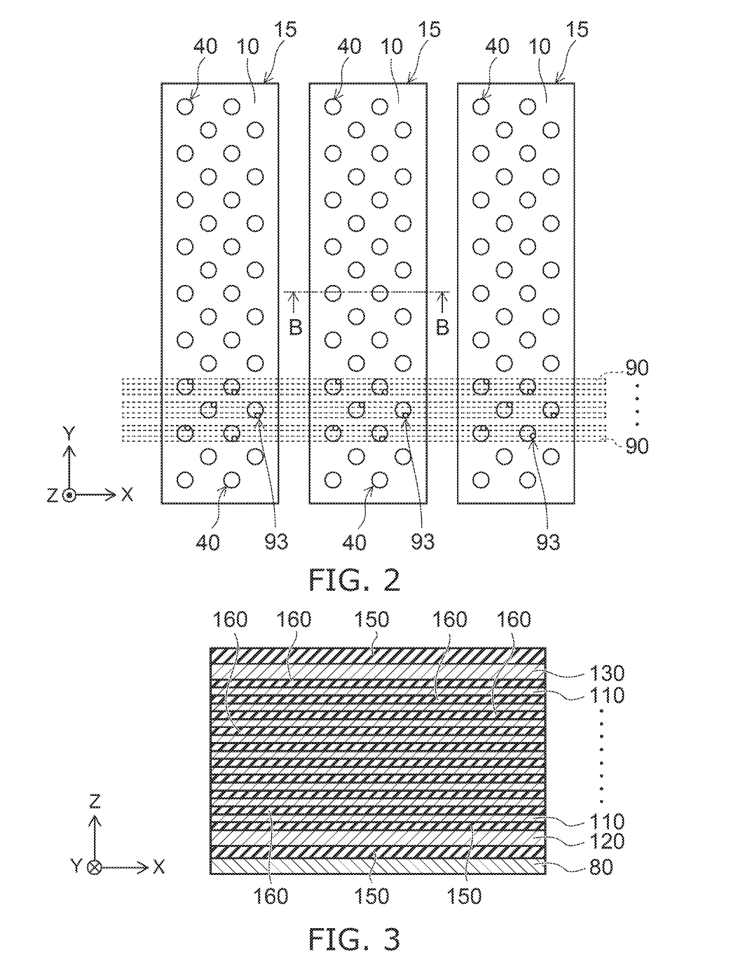

A semiconductor device 100 according to an embodiment will be described with reference to FIG. 1 and FIG. 2. FIG. 1 is a schematic cross-sectional view illustrating the semiconductor device 100 according to the embodiment. FIG. 2 is a schematic plan view illustrating the semiconductor device 100 according to the embodiment.

The semiconductor device 100 is, for example, a NAND type semiconductor memory device, and includes a memory cell array 1 that has a 3-dimensional structure. FIG. 1 is a cross-section along B-B line shown in FIG. 2. FIG. 1 omits an insulating film provided between respective elements. FIG. 2 shows a cross-section along A-A line shown in FIG. 1.

As shown in FIG. 1, the memory cell array 1 includes a plurality of word lines 10, and selection gates 20 and 30 which are stacked in a first direction (hereinafter, Z-direction). The selection gates 20 and 30 are disposed on both sides of the plurality of word lines 10 in the Z-direction. Each of the word lines 10, the selection gates 20 and 30 is a metal film, for example, such as tungsten (W) film or molybdenum (Mo) film. Alternatively, each of the word lines 10, the selection gate 20 and 30 may have a stacked structure that includes a barrier metal, such as titanium nitride (TiN) and the like, and a metal having higher conductivity than that of the barrier metal.

The memory cell array 1 includes at least one memory hole 40. The memory hole 40 pierces through the word lines 10 and the selection gates 20 and 30 in the Z-direction. A memory film 50 and a semiconductor layer 60 are provided on an inner surface of the memory hole 40. The memory film 50 and the semiconductor layer 60 extend in the Z-direction, respectively. Further, a core 70 may be formed on the semiconductor layer 60.

The memory film 50 has a stacked structure in which, for example, a silicon oxide film or a metal oxide film, a silicon nitride film, and a silicon oxide film are sequentially provided on the inner surface of the memory hole 40. The semiconductor layer 60 is, for example, a silicon layer. The core 70 is, for example, a silicon oxide film.

A memory cell MC is formed at a crossing portion of each word line 10 and the memory hole 40. The memory cell MC has a structure in which the memory film 50 is interposed between the word line 10 and the semiconductor layer 60. The memory film 50 is capable of storing charges and serves as a memory layer.

The memory cells MC are arranged in the Z-direction along the memory hole 40. A selection transistor STS and a selection transistor STD are provided on both sides of the memory cells MC arranged in the Z-direction. The selection transistor STS and the selection transistor STD have a structure in which the memory film 50 is interposed between one of the selection gates 20 and 30 and the semiconductor layer 60. In this case, the memory film 50 acts as a gate insulating film.

In this way, the memory cells MC, the selection transistor STS and the selection transistor STD are disposed along the memory hole 40. That is, one of NAND strings is provided in each memory hole 40.

A source layer 80 is provided on one side of the memory hole 40. A bit line 90 is provided on other side of the memory hole 40. The semiconductor layer 60 is electrically connected to the source layer 80. The source layer 80 is shared by the semiconductor layers 60 provided in the plurality of memory holes 40. The semiconductor layer 60 is electrically connected to the bit line 90. The semiconductor layer 60 is, for example, electrically connected to the bit line 90 via a contact plug 93.

As shown in FIG. 2, the word lines 10 extend in the Y-direction, respectively. The word lines 10 are disposed in parallel in the X-direction. The semiconductor device 100 includes a plurality of stacked body 15, and each stacked body 15 includes a plurality of word lines 10 stacked in the Z-direction. The stacked body 15 includes a plurality of memory holes 40. A plurality of bit lines 90 are provided across the plurality of stacked bodies 15, and each bit line 90 extends in the X-direction. The plurality of bit lines 90 are arranged in parallel in the Y-direction.

The semiconductor layer 60 provided in one of memory holes 40 that pierce through one of stacked bodies 15 is electrically connected to one of the bit lines 90. Thereby, it becomes possible to access one of NAND strings by selecting any one of the bit lines 90 and any one of the stacked bodies 15.

Specifically, a sensing amplifier (not shown) connected to one of the bit lines 90 may access one of NAND strings provided in a stacked body 15 in which the selection transistors STS and STD are in ON state. Furthermore, by setting one of word lines 10 stacked in the Z-direction to be different in an electrical potential from other word lines 10, it becomes possible to access one of the memory cells.

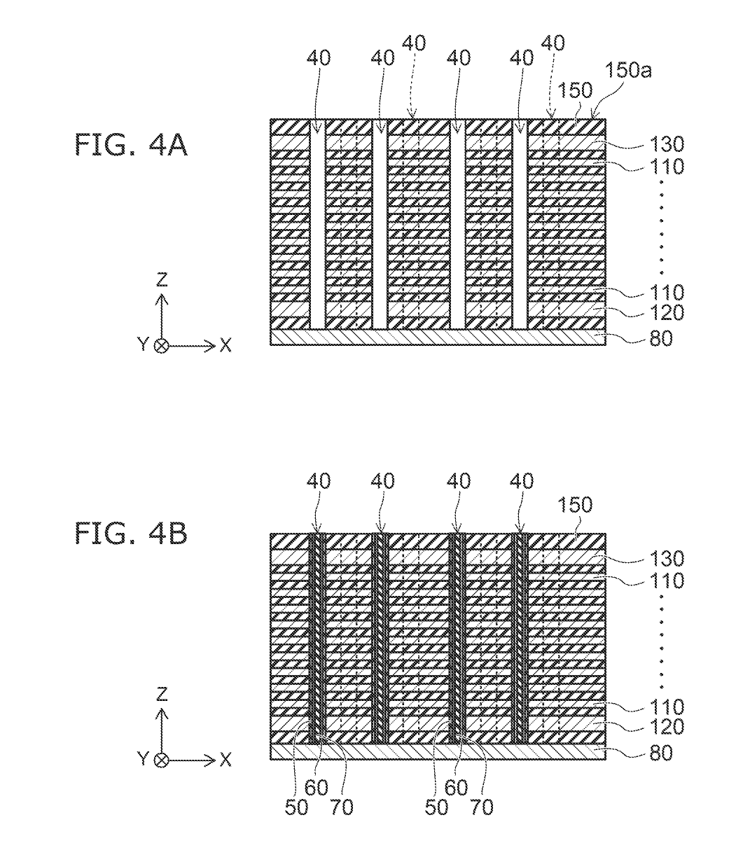

Next, a method for manufacturing the semiconductor device 100 according to the embodiment will be described with reference to FIG. 3, FIG. 4A to FIG. 5B. FIG. 3, FIG. 4A to FIG. 5B are schematic cross-sectional views showing the manufacturing process of the semiconductor device 100 according to the embodiment.

As shown in FIG. 3, a plurality of metal films 110, 120, and 130 are stacked on the source layer 80. The metal films 110, 120, and 130 are, for example, tungsten films. The metal films 110, 120, and 130 are, for example, formed by using a CVD (Chemical Vapor Deposition) method.

The metal film 120 is formed on the source layer 80 via an insulating film 150. The insulating film 150 is, for example, a silicon oxide film and is formed by using a plasma-enhanced CVD method.

The metal films 110 are stacked on the metal film 120 via the insulating film 150. Each of the metal films 110 is alternately stacked with an insulating film 160. The insulating film 160 is formed on each metal film 110. The insulating film 160 is, for example, a silicon oxide film.

The metal film 110 is divided into word lines 10 afterward (see FIG. 5A). In the finely-miniaturized memory cell array 1, the metal film 110 has a thickness of, for example, 20 nanometers (nm) to 30 nm in the Z-direction. Thus, an electrical resistance of the word lines 10 may increase, thereby decreasing access speed to the memory cell MC, in the case where an upper surface of the metal film 110 is oxidized while forming the insulating film 160. Hence, it is preferable in the process of forming the insulating film 160 to use a film formation method capable of suppressing the oxidation of the metal film 110.

Subsequently, a metal film 130 is formed on the uppermost layer insulating film 160. Further, the insulating film 150 is formed on the metal film 130.

Here, the metal film 110 and the insulating film 160 may be continuously deposited in a same deposition chamber. The metal film 110 may have a stacked structure which includes a barrier metal, such as TiN, and a tungsten film formed thereon. Alternatively, the metal film 110 may includes a stacked structure of TiN/W/TiN.

Next, as shown in FIG. 4, a plurality of memory holes 40 are formed. Using, for example, an RIE (Reactive Ion Etching) method, each of the memory holes 40 is formed with a depth to reach the source layer 80 from the upper surface 150a of the uppermost layer insulating film 150.

Next, as shown in FIG. 4B, the memory film 50, the semiconductor layer 60 and the core 70 are sequentially formed on the inner surface of the memory hole 40. The memory film 50, the semiconductor layer 60 and the core 70 are formed by using the CVD method or an ALD method, for example.

The memory film 50 includes, for example, a first silicon oxide film, a silicon nitride film, and a second silicon oxide film sequentially formed on the inner surface of the memory hole 40. The first silicon oxide film is provided between the word line 10 and the silicon nitride film, and acts as a block insulating film. A metal oxide film with a high dielectric constant may be used as the first silicon oxide film, for example.

The semiconductor layer 60 is a polycrystalline silicon layer formed on the memory film 50. The core 70 is a silicon oxide film formed on the semiconductor layer 60.

Next, as shown in FIG. 5A, a plurality of slits 170 are formed to divide the plurality of metal films 110, metal films 120 and 130 into a plurality of stacked bodies 15. The slits 170 are, for example, grooves extending in the Y-direction. The slits 170 are formed with a depth to reach the source layer 80 from the upper surface 150a of the uppermost layer by using the RIE method, for example. Each metal film 110 is divided into the plurality of word lines 10. The metal films 120 and 130 are divided into the selection gates 20 and 30, respectively.

Next, as shown in FIG. 5B, an insulating film 190 is formed to be embedded in the slits 170 and to cover the stacked bodies 15. The bit lines 90 are formed on the insulating film 190. Each of the bit lines 90 is electrically connected to the semiconductor layer 60 via a contact plug 93 that is formed in the insulating film 190. Further, an interlayer insulating film 195 is formed to cover the bit lines 90, then completing the semiconductor device 100.

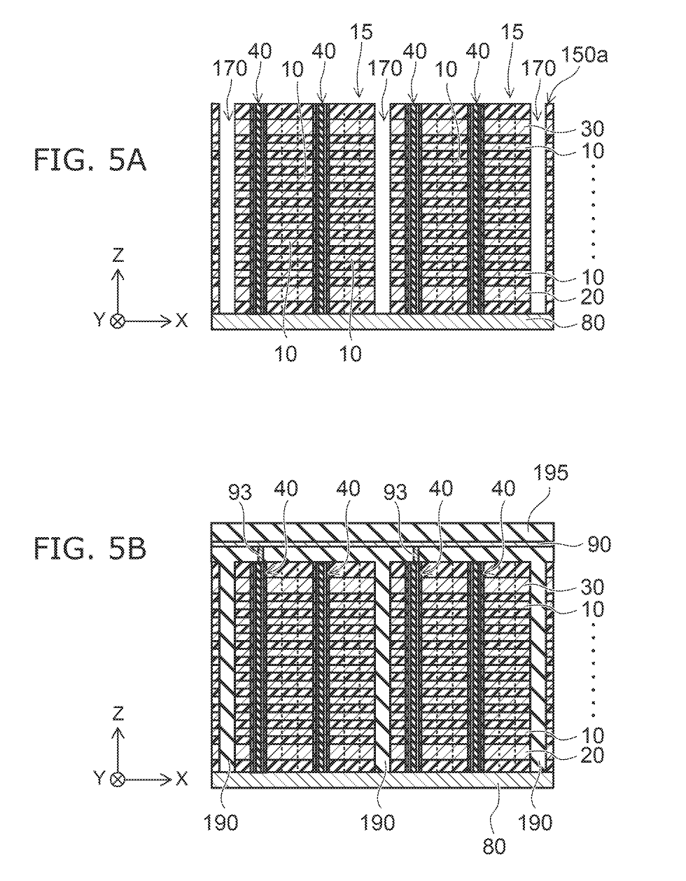

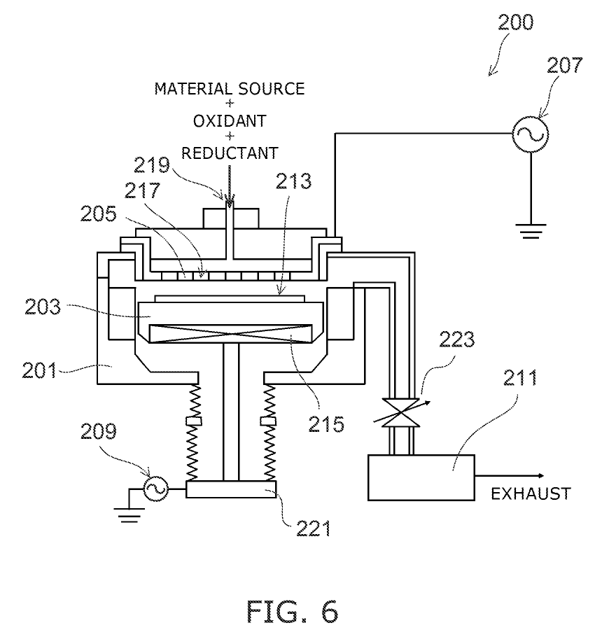

FIG. 6 is a schematic view showing a film formation apparatus 200 according to the embodiment. The apparatus 200 is, for example, a parallel plate type plasma-enhanced CVD apparatus.

As shown in FIG. 6, the apparatus 200 comprises a metal chamber 201, a wafer stage 203, a gas dispersion plate 205, radiofrequency power supplies 207 and 209, and a vacuum pump 211.

The wafer stage 203 is disposed inside the metal chamber 201 and holds a semiconductor wafer 213 set on the upper surface thereof. The wafer stage 203 serves as a lower electrode and is electrically connected to the radiofrequency power supply 209. The wafer stage 203 includes a heater block 215. The heater block 215 maintains the semiconductor wafer 213 at a prescribed temperature.

The gas dispersion plate 205 is disposed to face the wafer stage 203, and serves as an upper electrode. The radiofrequency power supply 207 is electrically connected to the gas dispersion plate 205. The gas dispersion plate 205 has a plurality of gas ejection holes 217, and disperses a mixed gas that includes a gaseous material source, a gaseous oxidant and a gaseous reductant over the upper surface of the wafer stage 203. Each flow of the gaseous material source, the gaseous oxidant and the gaseous reductant is controlled by a mass flow controller (not shown), and introduced from a gas port 219 that is provided in an upper portion of the metal chamber 201.

The wafer stage 203 is provided to be movable in up and down directions by a lift mechanism 221. The lift mechanism 221 may adjust a distance between the gas dispersion plate 205 and the semiconductor wafer 213.

The vacuum pump 211 exhausts a gas inside the metal chamber 201 via a throttle valve 223. The throttle valve 223 may keep the inside of the metal chamber 201 at a prescribed pressure.

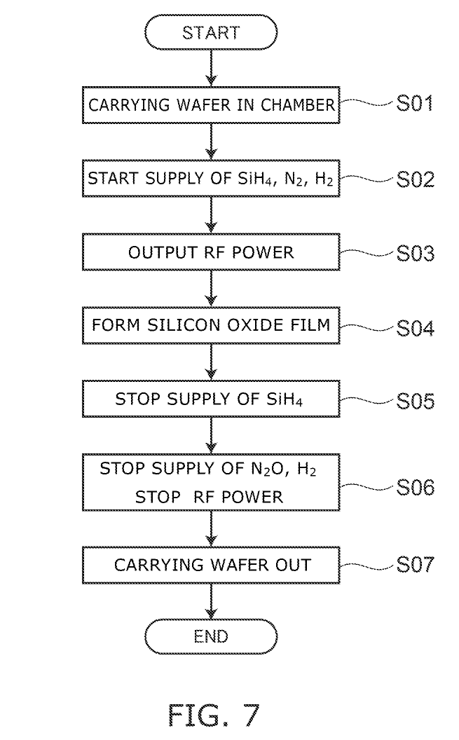

FIG. 7 is a flow chart showing a method for forming an insulating film according to the embodiment. For example, the insulating film 160 is formed in accordance with a procedure shown in FIG. 7 by using the film formation apparatus 200.

First, the semiconductor wafer 213 is carried in the metal chamber 201, and placed on the wafer stage 203 maintained at a temperature of 500° C., for example, by the heater block 215 (S01). The metal film 110 is provided on the semiconductor wafer 213.

Next, after exhausting the gas in the metal chamber 201 to make it a high vacuum state, the gaseous material source, the gaseous oxidant and the gaseous reductant are introduced via the gas port 219 (S02). The material source is, for example, monosilane (SiH₄). The oxidant is, for example, nitrous oxide (N₂O). The reductant is, for example, hydrogen (H₂). For example, SiH₄ is introduced at a flow rate of 140 sccm and N₂O is introduced at a flow rate of 8000 sccm into the metal chamber 201. The flow rate of H₂ is, for example, 1000 sccm.

Next, the pressure in the metal chamber 201 is controlled, for example, to be 5 Torr by using the throttle valve 223. Subsequently, after stabilizing the pressure in the metal chamber 201 and the gas flow rate, radiofrequency power is supplied onto the gas dispersion plate 205 and the wafer stage 203 (S03).

For example, the radiofrequency power of 1000 W is supplied to the gas dispersion plate 205 from the radiofrequency power supply 207. Simultaneously, for example, the radiofrequency power of 100 W is supplied to the wafer stage 203 from the radiofrequency power supply 209. This allows plasma to be generated between the wafer stage 203 and the gas dispersion plate 205. A bias may be applied between the wafer stage 203 and the gas dispersion plate 205 by supplying the radiofrequency power to the wafer stage 203.

SiH₄ and N₂O are plasma-excited in the plasma between the wafer stage 203 and the gas dispersion plate 205, and react on the semiconductor wafer 213. This allows the silicon oxide film (for example, insulating film 160) to be deposited on the semiconductor wafer 213 (504).

During the deposition process of the silicon oxide film, the surface of the metal film 110 is oxidized by oxygen radical dissociated from N₂O. In the deposition process according to the embodiment, however, the surface of the metal film 110 is reduced by radical hydrogen dissociated from H₂. As a result, the silicon oxide film can be formed, while suppressing oxidation of the metal film 110.

Next, the supply of SiH₄ is stopped (S05). Subsequently, the supply of N₂O and H₂ is stopped, and the supply of the radiofrequency power is stopped (S06), thereby finishing the deposition of the silicon oxide film.

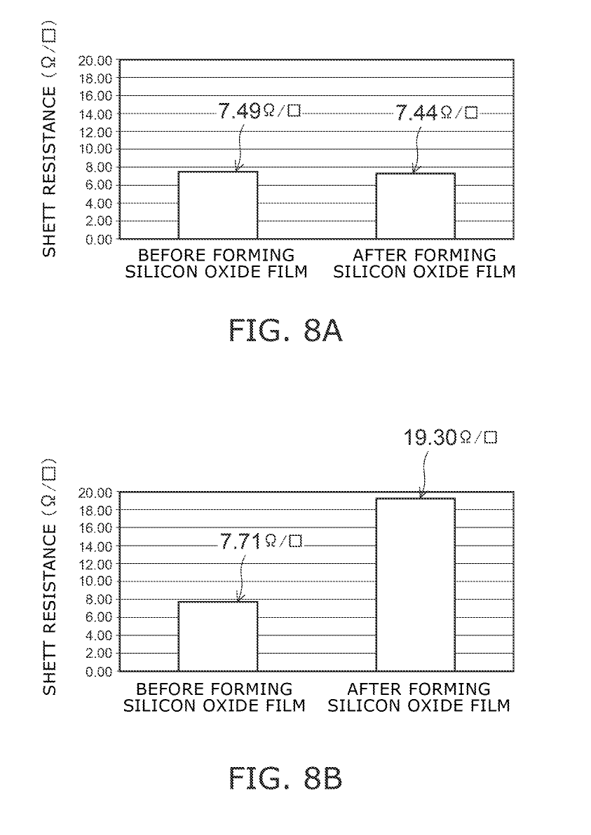

FIG. 8A and FIG. 8B are schematic views illustrating characteristics of the metal films 110 according to the embodiment and a comparative example.

FIG. 8A shows resistance change of the metal film 110 after forming the silicon oxide film according to the embodiment. As shown in FIG. 8A, the resistance value of the metal film 110 after forming the silicon oxide film is 7.44 Ω/□, and is approximately the same as the resistance value 7.49 Ω/□ before forming the silicon oxide film.

FIG. 8B shows resistance change of the metal film 110 after forming the silicon oxide film by using the film formation method according to the comparative example. In this example, SiH₄ and N₂O are used as material sources without supplying the reductant. As shown in FIG. 8B, the resistance value of the metal film 110 after forming the silicon oxide film is 19.30 Ω/□, and rises considerably from the resistance value 7.71 Ω/□ before forming the silicon oxide film.

In this manner, the oxidative N₂O and the reductive H₂ are simultaneously supplied in the process of depositing the silicon oxide film, thereby making it possible to form the film while suppressing the oxidation of the underlying metal film 110. Then, the electrical resistance of the metal film 110 is suppressed to increase, and it become possible to improve the characteristics of the semiconductor device 100.

In the process of forming a film by the plasma-enhanced CVD, it is preferable to make the flow rate of H₂ not less than 10% of the flow rate of N₂O, for example. This allows the silicon oxide film to be deposited while suppressing the oxidation of the metal film 110.

The embodiment is not limited to the above example. For example, oxygen (O₂) or ozone (O₃) may be used as the oxidant. SiH₄ may be replaced with disilane (Si₂H₆) or tetraorganosilane ((R—O)₄Si). It is preferable to use tetraorganosilane of alkoxy group such as tetraethoxysilane (TEOS), tetramethoxysilane or the like.

A deposition method may be used, in which the film is deposited by supplying the material source and the oxidant, while the reductant is supplied in an initial period of the deposition time and not supplied in a remaining period.

Furthermore, a treatment for cleaning a surface of the metal film 110 may be applied before depositing the silicon oxide film. More specifically, the surface of the metal film 110 may be subjected to a plasma treatment by using plasma of an inert gas such as argon (Ar) and like before supplying SiH₄ and N₂O to deposit the silicon oxide film, for example. This allows organic molecules or the like adsorbed on the surface of the metal film 110 to be removed, and the adhesion between the silicon oxide film and the metal film 110 may be improved, for example.

Before depositing the silicon oxide film, for example, argon (Ar) and H₂ may be supplied to apply the plasma treatment to the surface of the metal film 110. The metal oxide film formed on the surface of the metal film 110 may be reduced and removed by adding H₂. This allows the adhesion between the silicon oxide film and the metal film 110 to be improved, and the electrical resistance of the metal film 110 may be lowered, for example.

For example, after treating the surface of the metal film 110 using plasma of the inert gas such as argon (Ar) and like, the surface of the metal film 110 may be treated using plasma under supplying H₂. In this manner, performing two steps pre-treatment allows the adhesion between the silicon oxide film and the metal film 110 to be further improved, and thereby the electrical resistance of the metal film 110 may be decreased. It is possible to reverse the sequence of the two steps pre-treatment.

Although not described explicitly in the above embodiment, the inert gas such as helium and argon may be added to the mixed gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A film formation method comprising:
forming a metal film on an underlying layer; and
depositing an oxide film on the metal film using plasma of a mixed gas induced above the metal film, the mixed gas including a gaseous material source, a gaseous oxidant, and a gaseous reductant.

2. The method according to claim 1, wherein
the gaseous material source includes one of monosilane, disilane, tetraethoxysilane and tetramethoxysilane; and the oxide film is a silicon oxide film.

3. The method according to claim 1, wherein
the gaseous oxidant includes one of nitrous oxide and nitrogen oxide.

4. The method according to claim 1, wherein
the gaseous reductant includes at least one selected from hydrogen, nitrogen monoxide, and carbon monoxide.

5. The method according to claim 1, wherein
the gaseous reductant is supplied in an initial period of a deposition time of the oxide film, and not supplied in a remaining period.

6. The method according to claim 1, wherein
a plurality of metal films stacked via the oxide film are formed on the underlying layer by repeating the steps of forming the metal film and depositing the oxide film.

7. The method according to claim 1, further comprising:
treating a surface of the metal film using inert gas plasma before depositing the oxide film.

8. The method according to claim 7, further comprising:
treating the surface of the metal film using reductive gas plasma after the treatment using the inert gas plasma.

9. The method according to claim 1, further comprising:
treating a surface of the metal film using reductive gas plasma before depositing the metal film; and
treating the surface of the metal film using inert gas plasma after the treatment using the reductive gas plasma.

10. The method according to claim 1, further comprising:
treating a surface of the metal film before depositing the oxide film, using plasma of a mixed gas that includes an inert gas and a gaseous reductant.

11. The method according to claim 1, wherein
the metal film is one of a tungsten film and a molybdenum film.

12. The method according to claim 1, wherein
plasma is induced between a first electrode and a second electrode, wherein a wafer including the underlying layer is placed on the first electrode, and a second electrode having a plurality of holes through which the mixed gas is supplied; and
the oxide film is deposited under a prescribed bias applied between the first electrode and the second electrode.

13. The method according to claim 1, wherein the metal film and the oxide film are continuously deposited in a same deposition chamber.

14. A method for manufacturing a semiconductor device comprising:
forming a plurality of metal films stacked on an underlying layer comprising:
forming an initial metal film on the underlying layer;
depositing an oxide film on the initial metal film using plasma of a mixed gas induced above the initial metal film, the mixed gas including a gaseous material source, a gaseous oxidant, and a gaseous reductant; and
repeating steps of forming a metal film on the oxide film and depositing an oxide film on the metal film using plasma of the mixed gas;
forming a memory hole piercing through the plurality of metal films in the stacking direction;
forming a memory film on an inner surface of the memory hole; and
forming a semiconductor layer on the memory film inside the memory hole.

15. The method according to claim 14, wherein
the gaseous material source includes one of monosilane, disilane, tetraethoxysilane and tetramethoxysilane; and the oxide film is a silicon oxide film.

16. The method according to claim 14, wherein
each of the plurality of metal films is one of a tungsten film and a molybdenum film.

17. The method according to claim 14, wherein
each of the plurality of metal films has a stacked structure that includes a barrier metal and a metal having higher conductivity than a conductivity of the barrier metal.

18. The method according to claim 14, wherein
each of the plurality of metal films and the oxide film are continuously deposited in a same deposition chamber.
